(19) United States
(12) Patent Application Publication
(10) Pub. No.: US 2006/0060853 A1
(43) Pub. Date: Mar. 23, 2006

(54) Display, array substrate, and display manufacturing method

(76) Inventor: Makoto Shibusawa, Fukaya-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/208,653

(22) Filed: Aug. 23, 2005

(30) Foreign Application Priority Data
Sep. 22, 2004 (JP) 2004-276033

(51) Int. Cl. H01L 29/04; H01L 21/84

(52) U.S. Cl. 257/59; 257/72; 438/157

(57) ABSTRACT

Each pixel of a display includes first and second thin film transistors different in conduction type from each other and connected in series between a first power supply terminal and an input/output terminal in this order, a first capacitor connected between a gate of the first thin film transistor and a constant potential terminal, a first diode-connecting switch connected between the gate and drain of the first thin film transistor, a second capacitor connected between gate and source of the second thin film transistor, a second diode-connecting switch connected between the gate and drain of the second thin film transistor, a display element, an output control switch, the output control switch and the display element being connected in series between the input/output terminal and a second power supply terminal in this order, and a video signal supply control switch connected between the input/output terminal and a video signal line.

### CROSS-REFERENCE TO RELATED APPLICATIONS

This application is based upon and claims the benefit of priority from prior Japanese Patent Application No. 2004-276033, filed Sep. 22, 2004, the entire contents of which are incorporated herein by reference.

### BACKGROUND OF THE INVENTION

1. Field of the Invention

The present invention relates to a display, array substrate, and display manufacturing method.

2. Description of the Related Art

In a display such as an organic electroluminescent (EL) display which controls the optical behaviors of display elements by driving currents supplied to the display elements, if the driving currents vary, the image quality becomes poor due to, e.g., luminance unevenness. Therefore, in the case where such a display uses an active matrix driving method, it is required that drive control elements of pixels which control a magnitude of the drive current have substantially uniform properties. However, in this display, in general, the drive control elements are formed on an insulator such as a glass substrate, and thus, their properties readily vary.

In U.S. Pat. No. 6,373,454, there is described an organic EL display employing a current-copy type circuit in a pixel circuit.

The current-copy type pixel circuit includes an n-channel field effect transistor (FET) as a drive control element, organic EL element and capacitor. The source of the n-channel FET is connected to a power supply line which is set at a lower electric potential, and the capacitor is connected between a gate of the n-channel FET and the power supply line. In addition, the anode of the organic EL element is connected to a power supply line which is set at a higher electric potential.

The pixel circuit is driven in accordance with the following method.

First, the drain and gate of the n-channel FET are connected to each other. In this state, an electric current I_{sig} having a magnitude corresponding to a video signal is made flow between the drain and source of the n-channel FET. By this operation, the voltage between two electrodes of the capacitor is set at a gate-to-source voltage necessary for the electric current I_{sig} to flow through the channel of the n-channel FET.

Then, the drain and gate of the n-channel FET are disconnected from each other, and the voltage between the electrodes of the capacitor is maintained. Subsequently, the drain of the n-channel FET is connected to the cathode of the organic EL element. As a consequence, a driving current having a magnitude substantially equal to that of the electric current I_{sig} flows through the organic EL element. The organic EL element emits light at luminance corresponding to the magnitude of this driving current.

As described above, when the current-copy circuit is employed in a pixel circuit, the driving current with a magnitude substantially equal to that of the electric current I_{sig}, which is made flow as a video signal during the write period, can flow between the drain and source of the n-channel FET during the holding period next to the write period. For this reason, not only the influence of the threshold value Vth of the n-channel FET but also the influence of its mobility and dimensions on the drive current can be eliminated.

The present inventor, however, has found that display unevenness can occur even in a display which employs the current-copy circuit in a pixel circuit.

### BRIEF SUMMARY OF THE INVENTION

According to a first aspect of the present invention, there is provided a display comprising an insulating substrate, pixels arrayed in a matrix form on the insulating substrate, and video signal lines arranged correspondently with columns which the pixels form, wherein each of the pixels comprises a first thin film transistor, a second thin film transistor different in conduction type from the first thin film transistor, the first and second thin film transistors being connected in series between a first power supply terminal and an input/output terminal in this order, a first capacitor connected between a gate of the first thin film transistor and a constant potential terminal, a first diode-connecting switch connected between the gate and drain of the first thin film transistor, a second capacitor connected between gate and source of the second thin film transistor, a second diode-connecting switch connected between the gate and drain of the second thin film transistor, a display element, an output control switch, the output control switch and the display element being connected in series between the input/output terminal and a second power supply terminal in this order, and a video signal supply control switch connected between the input/output terminal and the video signal line.

According to a second aspect of the present invention, there is provided an array substrate comprising an insulating substrate, pixel circuits arrayed in a matrix form on the insulating substrate, and video signal lines arranged correspondently with columns which the pixel circuits form, wherein each of the pixel circuits comprises a first thin film transistor, a second thin film transistor different in conduction type from the first thin film transistor, the first and second thin film transistors being connected in series between a power supply terminal and an input/output terminal in this order, a first capacitor connected between a gate of the first thin film transistor and a constant potential terminal, a first diode-connecting switch connected between the gate and drain of the first thin film transistor, a second capacitor connected between gate and source of the second thin film transistor, a second diode-connecting switch connected between the gate and drain of the second thin film transistor, a pixel electrode, an output control switch connected between the input/output terminal and the pixel electrode, and a video signal supply control switch connected between the input/output terminal and the video signal line.

According to a third aspect of the present invention, there is provided a method of manufacturing the display according to the first aspect, comprising forming first and second semiconductor layers in which the sources and drains of the first and second thin film transistors are to be formed, respectively, at positions on the insulating substrate corresponding to the pixels, and simultaneously executing channel doping for the first semiconductor layer and channel doping for the second semiconductor layer at each of the positions corresponding to the pixels.

### BRIEF DESCRIPTION OF THE SEVERAL VIEWS OF THE DRAWING

FIG. 1 is a plan view schematically showing a display according to the first embodiment of the present invention;

FIG. 2 is a partial sectional view showing an example of a structure usable in the display shown in FIG. 1;

FIG. 3 is a timing chart schematically showing an example of a driving method of the display shown in FIG. 1;

FIG. 4 is an equivalent circuit diagram showing a modification of a pixel shown in FIG. 1;

FIG. 5 is an equivalent circuit diagram of a pixel included in a display according to the second embodiment of the present invention;

FIG. 6 is an equivalent circuit diagram showing a modification of the pixel shown in FIG. 4; and

FIG. 7 is an equivalent circuit diagram showing a modification of the pixel shown in FIG. 5.

### DETAILED DESCRIPTION OF THE INVENTION

Several embodiments of the present invention will be described in detail below with reference to the accompanying drawing. The same reference numerals denote parts which achieve the same or similar functions in the drawing, and a repetitive explanation thereof will be omitted.

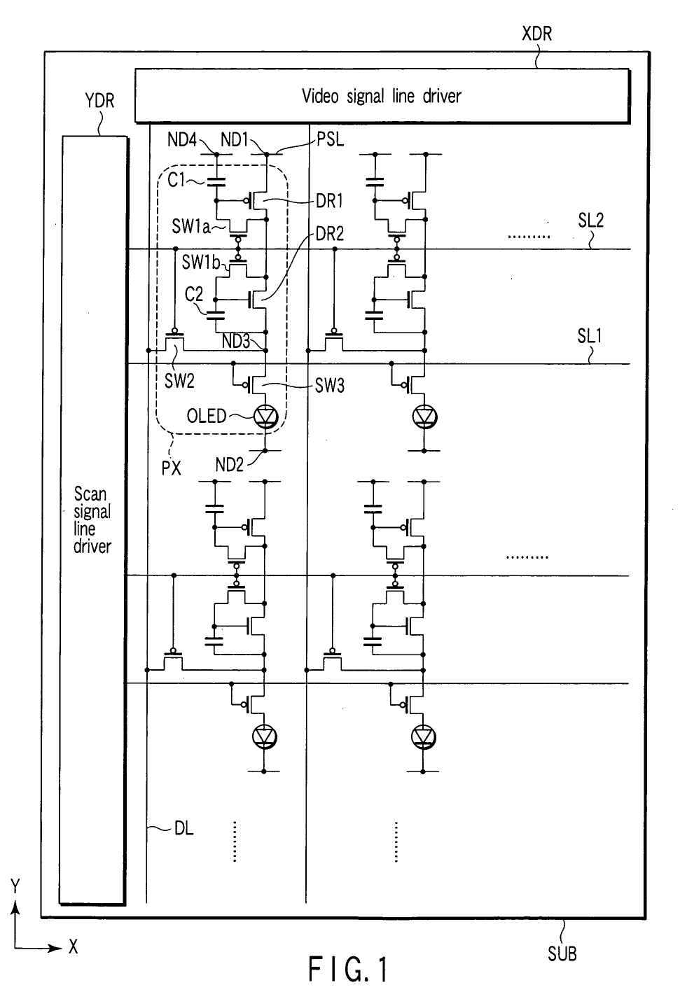

FIG. 1 is a plan view schematically showing a display according to the first embodiment of the present invention.

The display is an active matrix display, e.g., an active matrix organic EL display, and includes pixels PX. The pixels PX are arranged in a matrix on an insulating substrate SUB such as a glass substrate.

A scan signal line driver YDR and video signal line driver XDR are arranged on the substrate SUB.

On the substrate SUB, scan signal lines SL1 and SL2 run in the row direction (X-direction) of the matrix of the pixels PX, and are arranged in the column direction (Y-direction) of the matrix of the pixels PX. The scan signal lines SL1 and SL2 are connected to the scan signal line driver YDR which supplies the scan signal lines SL1 and SL2 with voltage signals as scan signals.

Also, on the substrate SUB, video signal lines DL run in the Y-direction and are arranged in the X-direction. The video signal lines DL are connected to the video signal line driver XDR which supplies the video signal lines DL with video signals.

In addition, power supply lines PSL are arranged on the substrate SUB.

The pixel PX includes a pixel circuit, active layer and counter electrode (to be described later). The pixel circuit includes a first drive control element DR1, second drive control element DR2, diode-connecting switch SW1a, diode-connecting switch SW1b, video signal supply control switch SW2, output control switch SW3, capacitor C1, capacitor C2, and pixel electrode (not shown). The pixel electrode, active layer, and counter electrode form a display element OLED.

The display element OLED includes an anode and cathode facing each other, and the active layer which changes its optical behaviors in accordance with an electric current which flows between the anode and cathode. As an example, the display element OLED is an organic EL element including at least a light-emitting layer as the active layer. Also, for example, the anode is a pixel electrode as a lower electrode, and the cathode is a counter electrode as an upper electrode which faces the lower electrode with the active layer interposed therebetween.

The first drive control element DR1 is a thin-film transistor (to be referred to as a TFT hereinafter) having a source, drain, and channel formed in a polycrystalline semiconductor layer. As an example, a p-channel TFT having a polysilicon layer as the polycrystalline semiconductor layer is used as the first drive control element DR1. The source of the first drive control element DR1 is connected to the power supply line PSL. A node ND1 on the power supply line PSL corresponds to a first power supply terminal.

The second drive control element DR2 is a TFT having a source, drain, and channel formed in a polycrystalline semiconductor layer, and different in conduction type from the first drive control element DR1. As an example, an n-channel TFT having a polysilicon layer as the polycrystalline semiconductor layer is used as the second drive control element DR2. The second drive control element DR2 has a source connected to a node ND3 as an input/output terminal, and a drain connected to the drain of the first drive control element DR1.

The diode-connecting switch SW1a is connected between the drain and gate of the first drive control element DR1. A switching operation of the diode-connecting switch SW1a is controlled by, e.g., a scan signal supplied from the scan signal line driver YDR via the scan signal line. For example, a p-channel TFT is used as the diode-connecting switch SW1a, and the gate of this TFT is connected to the scan signal line SL2.

The diode-connecting switch SW1b is connected between the drain and gate of the second drive control element DR2. A switching operation of the diode-connecting switch SW1b is controlled by, e.g., a scan signal supplied from the scan signal line driver YDR via the scan signal line. For example, a p-channel TFT is used as the diode-connecting switch SW1b, and the gate of this TFT is connected to the scan signal line SL2.

The video signal supply control switch SW2 is connected between the node ND3 and video signal line DL. As an example, a p-channel TFT is used as the video signal supply control switch SW2, and the gate of this TFT is connected to the scan signal line SL2.

The output control switch SW3 and display element OLED are connected in series between the node ND3 and a second power supply terminal ND2. In this embodiment, a p-channel TFT is used as the output control switch SW3. The gate of this TFT is connected to the scan signal line SL1, and the source and drain of the TFT are connected to the node ND3 and the anode of the display element OLED, respectively. The electric potential of the second power supply terminal ND2 is lower than that of the first power supply terminal ND1.

The capacitor C1 is connected between the gate of the first drive control element DR1 and a constant-potential terminal ND4. In a display period following a write period, the capacitor C1 holds the gate-to-source voltage of the first drive control element DR1 substantially constant.

The capacitor C2 is connected between the gate and source of the second drive control element DR2. In a display period following a write period, the capacitor C2 holds the gate-to-source voltage of the second drive control element DR2 substantially constant.

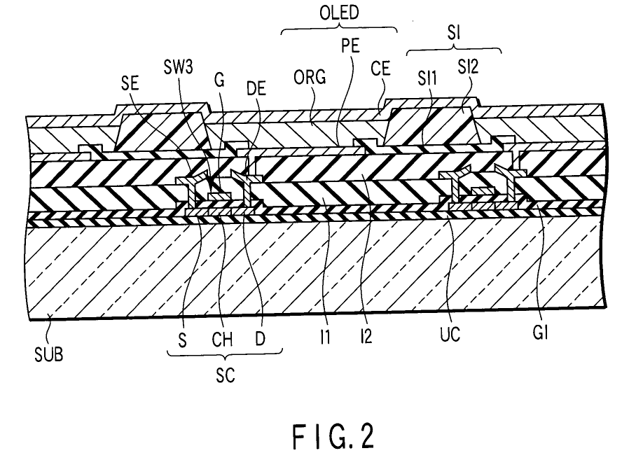

FIG. 2 is a partial sectional view showing an example of a structure usable in the display shown in FIG. 1. Although FIG. 2 shows only the output control switch SW3 as a TFT, the diode-connecting switches SW1a and SW1b and video signal supply control switch SW2 have the same structure as the output control switch SW3. Also, the first drive control element DR1 has substantially the same structure as the output control switch SW3. In addition, the second drive control element DR2 has substantially the same structure as the first drive control element DR1 except for the conduction types of a source S and drain D (to be described later).

As shown in FIG. 2, an undercoat layer UC is formed on one major surface of the insulating substrate SUB. As the undercoat layer UC, it is possible to use, e.g., a layered structure of an SiNₓ layer and SiO₂ layer.

On the undercoat layer UC, patterned polysilicon layers are formed as polycrystalline semiconductor layers SC. The polycrystalline semiconductor layers SC can be formed by, e.g., the following method.

First, an amorphous semiconductor layer is formed on the undercoat layer UC. The amorphous semiconductor layer can be formed by, e.g., plasma CVD (PECVD: plasma enhanced chemical vapor deposition). As an example, an amorphous silicon layer can be formed by plasma CVD using silane gas as a raw material gas.

Next, the amorphous semiconductor layer is subjected to a fusing and recrystallization process, and then patterned. For the fusing and recrystallization process, for example, a laser annealing using an excimer laser such as a XeCl excimer laser can be utilized. In addition, photolithography and etching can be utilized for patterning of the semiconductor layer. As described above, the crystalline semiconductor layers SC are obtained.

In each polycrystalline semiconductor layer SC, formed are source S and drain D of the TFT which are spaced from each other. A region CH between the source S and drain D in the semiconductor layer SC is used as a channel.

Before forming a gate G, the polycrystalline semiconductor layer SC is subjected to an ion doping process in order to adjust the threshold voltage of the TFT. That is, channel doping is performed. An ion beam used in the ion doping can be a line beam or plane beam.

In this embodiment, channel doping for the semiconductor layer SC of the first drive control element DR1 included in each pixel PX is performed simultaneously with channel doping for the semiconductor layer SC of the second drive control element DR2 included in the same pixel PX.

That is, when a line beam is used as the ion beam, the major surface of the substrate SUB on which the polycrystalline semiconductor layers SC are formed is irradiated with the line ion beam, while both the semiconductor layer SC of the first drive control element DR1 and the semiconductor layer SC of the second drive control element DR2 are exposed. The position of an irradiated area on the substrate SUB which is irradiated with the ion beam is moved in a direction crossing the longitudinal direction of the irradiated area.

When a plane beam is used as the ion beam, the major surface of the substrate SUB on which the polycrystalline semiconductor layers SC are formed is irradiated with this plane ion beam, while both the semiconductor layer SC of the first drive control element DR1 and the semiconductor layer SC of the second drive control element DR2 are exposed.

The source S and drain D can be formed by, e.g., ion doping using the gate G as a mask. An ion beam used in this ion doping can be a line beam or plane beam. If necessary, impurity activation may also be performed in any stage after ion doping.

Note that the conduction types of the first and second drive control elements DR1 and DR2 are different from each other. Therefore, in one of the first and second drive control elements DR1 and DR2, the source S and drain D are formed by doping the semiconductor layer SC with an acceptor as a majority carrier. In the other of the first and second drive control elements DR1 and DR2, the source S and drain D are formed by doping the semiconductor layer SC with a donor as a majority carrier. In this embodiment, the first drive control element DR1 is a p-channel TFT, so its semiconductor layer SC is doped with an acceptor as a majority carrier. Since the second drive control element DR2 is an n-channel TFT, its semiconductor layer SC is doped with a donor as a majority carrier.

A gate insulator G1 is formed on the semiconductor layer SC. First conductor patterns and an insulating film I1 are sequentially formed on the gate insulator G1. The first conductor patterns are used as the gate G of the TFT, first electrodes (not shown) of the capacitors C1 and C2, the scan signal lines SL1 and SL2, and interconnections which connect these elements. The insulating film I1 is used as an interlayer dielectric film and dielectric layers of the capacitors C1 and C2.

Second conductor patterns are formed on the insulating film I1. The second conductor patterns are used as a source electrode SE, a drain electrode DE, second electrodes (not shown) of the capacitors C1 and C2, the video signal lines DL, the power supply lines PSL, and interconnections which connect these elements. In the positions of through holes formed in the insulating films G1 and I1, the source electrode SE and drain electrode DE are connected to the source S and drain D, respectively, of the TFT.

An insulating film I2 and third conductor patterns are sequentially formed on the second conductor patterns and the insulating film I1. The insulating film I2 is used as a passivation film and/or a planarizing layer. The third conductor patterns are used as pixel electrodes PE of the organic EL elements OLED. As an example, the pixel electrode PE is an anode.

A through hole is formed in the insulating film I2 for each pixel PX. This through hole reaches the drain electrode DE connected to the drain D of the output control switch SW3. Each pixel electrode PE covers the sidewall and bottom surface of the through hole. In this manner, the pixel electrode PE is connected to the drain D of the output control switch SW3 via the drain electrode DE.

A partition insulating layer SI is formed on the insulating film I2. In this embodiment, the partition insulating layer SI has a layered structure of an inorganic insulating layer SI1 and organic insulating layer SI2. However, the inorganic insulating layer SI1 may be omitted.

The partition insulating layer SI has through holes in the positions of the pixel electrodes PE. In each through hole of the partition insulating layer SI, an active layer ORG including a light-emitting layer is deposited on the pixel electrode PE. The light-emitting layer is, e.g., a thin film containing a red, green, or blue luminescent organic compound. In addition to this light-emitting layer, the active layer ORG can further include, e.g., a hole injecting layer, hole transporting layer, electron injecting layer, and electron transporting layer. These layers forming the active layer ORG can be formed by, e.g., a mask evaporation method or inkjet method.

A counter electrode CE is formed on the partition insulating layer SI and active layer ORG. The counter electrode CE is electrically connected to an electrode interconnection which provides the node ND2, via a contact hole (not shown) formed in the insulating films I1 and I2 and partition insulating film SI. In this embodiment, the counter electrode CE is a cathode as an example and is continuously formed and common to all pixels.

Each organic EL element OLED is made up of the pixel electrode PE, active layer ORG, and counter electrode CE.

Note that in this display, the substrate SUB, the pixel electrodes PE, and the members interposed between them form an array substrate. This array substrate can further include the partition insulating layer SI. The array substrate can also further include the scan signal line driver YDR and video signal line driver XDR shown in FIG. 1.

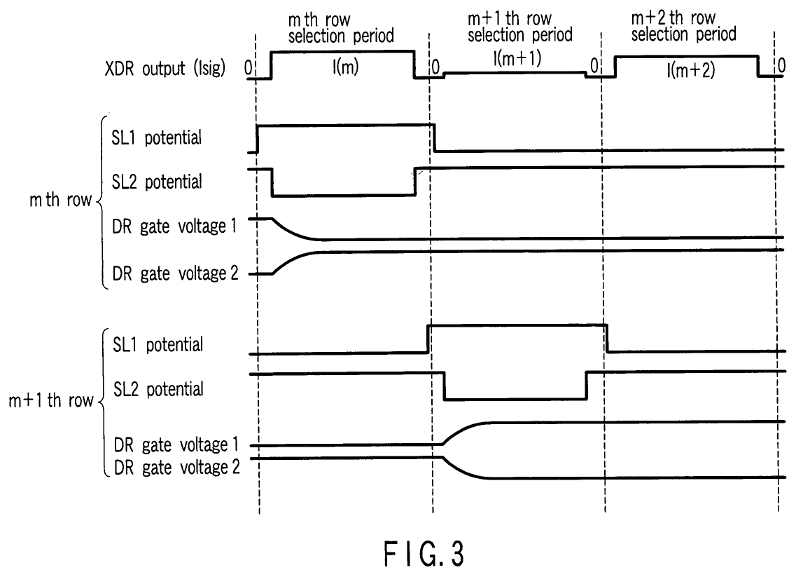

FIG. 3 is a timing chart schematically showing an example of a method of driving the display shown in FIG. 1.

Referring to FIG. 3, the abscissa represents the time, and the ordinates represent the magnitude of an electric potential or electric current. Also, in FIG. 3, a waveform indicated by “XDR output (I_{sig})” shows an electric current which the video signal line driver XDR makes flow through the video signal line DL. Waveforms indicated by “SL1 potential” and “SL2 potential” show the electric potentials of the scan signal lines SL1 and SL2, respectively. Waveforms indicated by “DR gate voltage 1” and “DR gate voltage 2” show the gate-to-source voltage of the first drive control element DR1 and the gate-to-source voltage of the second drive control element DR2, respectively.

According to the method of FIG. 3, the display shown in FIG. 1 is driven as follows.

In the case of displaying some gray level on a pixel PX arranged in the mth row, during a period of selecting the pixels PX in the mth row, i.e., the mth row selection period, for example, the electric potential of the scan signal line SL1 is first changed from a second electric potential which makes the output control switch SW3 ON state to a first electric potential which makes the output control switch SW3 OFF state, thereby opening the output control switch SW3 (non-conducting state). The following write operation is carried out during a write period in which the output control switch SW3 is opened.

That is, for example, the electric potential of the scan signal line SL2 is changed from a third electric potential which makes the diode-connecting switches SW1a and SW1b and video signal supply control switch SW2 OFF state to a fourth electric potential which makes the switches SW1a, SW1b and SW2 ON state, thereby closing the diode-connecting switches SW1a and SW1b and video signal supply control switch SW2 (conducting state). In this manner, the drain and gate of the first drive control element DR1 are connected, the drain and gate of the second drive control element DR2 are connected, and the node ND3 and video signal line DL are connected.

In this state, the video signal line driver XDR supplies the selected pixel PX with a video signal via the video signal line DL. That is, by means of the video signal driver XDR, a current Iₒᵤₜ is made flow from the power supply terminal ND1 to the video signal line DL. The magnitude of the current Iₒᵤₜ corresponds to the magnitude of a drive current flowing through the display element OLED of the selected pixel PX, i.e., a gray level to be displayed on the selected pixel PX.

By carrying out this write operation, the gate-to-source voltage of the first drive control element DR1 is set at a value V_{gs}1 when the current Iₒᵤₜ flows between its source and drain. At this time, the gate-to-source voltage of the second drive control element DR2 is set at a value V_{gs}2 when the current Iₒᵤₜ flows between its source and drain.

The source potential of the first drive control element DR1 is equal to the electric potential of the first power supply terminal ND1. That is, the source potential of the first drive control element DR1 is constant throughout the write period in which the output control switch SW3 is open and an effective display period in which the output control switch SW3 is closed. On the other hand, the gate potential of the first drive control element DR1 is held by the capacitor C1 during the effective display period. Accordingly, setting the gate potential of the first drive control element DR1 at an electric potential V_{g}1 corresponding to the electric current I_{sig} by the write operation described above is equivalent to setting the gate voltage (gate-to-source voltage) of the first drive control element DR1 at the voltage V_{gs}1 corresponding to the electric current I_{sig}.

Also, the gate-to-source voltage of the second drive control element DR2 is held by the capacitor C2 during the effective display period. Therefore, setting the gate-to-source voltage of the second drive control element DR2 at a voltage corresponding to the electric current I_{sig} by the above-mentioned write operation is equivalent to setting the gate-to-source voltage of the second drive control element DR2 during the effective display period at the voltage V_{gs}2 corresponding to the electric current I_{sig}.

Next, for example, the electric potential of the scan signal line SL2 is changed from the fourth electric potential to the third electric potential, thereby opening the diode-connecting switches SW1a and SW1b and video signal supply control switch SW2 (non-conducting state). That is, the drain and gate of the first drive control element DR1 are disconnected from each other, the drain and gate of the second drive control element DR2 are disconnected from each other, and the node ND3 and the video signal line DL are disconnected from each other. Then, in this state, the electric potential of the scan signal line SL1 is changed from the first electric potential to the second electric potential, thereby closing the output control switch SW3 (conducting state).

As described above, by the write operation, the gate potential of the first drive control element DR1 is set at a value V_{g}1 when the current Iₒᵤₜ flows. The gate potential V_{g}1 is maintained until the diode-connecting switch SW1 and video signal supply control switch SW2 are closed. Therefore, during an effective display period in which the switch SW3 is closed, the first drive control element DR1 controls the driving current flowing through the display element OLED to have a magnitude corresponding to the electric current I_{sig}. The gate-to-source voltage of the second drive control element DR2 is also set at the value V_{gs}2 when the electric current I_{sig} flows. The gate voltage V_{gs}2 is maintained until the diode-connecting switch SW1b and video signal supply control switch SW2 are closed. Accordingly, in the effective display period, the second drive control element DR2 also controls the driving current flowing through the display element OLED to have a magnitude corresponding to the electric current I_{sig}.

In the effective display period during which the output control switch SW3 is closed, therefore, the first and second drive control elements DR1 and DR2 control the driving current flowing through the display element OLED to have a magnitude corresponding to the electric current I_{sig}. As a consequence, the display element OLED displays a gray scale corresponding to the magnitude of the driving current.

As described previously, the conventional display using the current-copy circuit as a pixel circuit may cause display unevenness. That is, display unevenness may occur if the second drive control element DR2, diode-connecting switch SW1b, and capacitor C2 are omitted from the display shown in FIG. 1, and the display is driven by the method shown in FIG. 3. The present inventor examined the cause of this problem, and has found that in the display having no second drive control element DR2, variations in threshold voltages of the first drive control elements DR1 in each column formed by the pixels PX cause the display unevenness. This will be explained in detail below.

Assume that in the display having no second drive control element DR2, the same gray scale is to be displayed by the pixel PX in the mth row and the pixel PX in the (m+1)th row connected to the same video signal line DL. In this case, the output electric current I_{sig} of the video signal line driver XDR during the write period of the pixel PX in the mth row is equal to the output electric current I_{sig} of the video signal line driver XDR during the write period of the pixel PX in the (m+1)th row.

When the display having no second drive control element DR2 is driven by the method shown in FIG. 3, immediately after the write period of the pixel PX in the mth row, the gate potential of the first drive control element DR1 included in the pixel PX is set at a value V_{g}1(m) when the electric current I_{sig} flows through the source-to-drain path of the first drive control element DR1. Likewise, immediately after the write period of the pixel PX in the (m+1)th row, the gate potential of the first drive control element DR1 included in the pixel PX is set at a value V_{g}1(m+1) when the electric current I_{sig} flows through the source-to-drain path of the first drive control element DR1.

In the display having no second drive control element DR2, however, if the electric current I_{sig} is small and the first drive control elements DR1 of the pixels PX in the mth and (m+1)th rows have different threshold values, the gate potential of the first drive control element DR1 included in the pixel PX in the (m+1)th row cannot be accurately set at V_{g}1(m+1) during the write period of the pixel PX in the (m+1)th row owing to the effect of the parasitic capacitance of the video signal line DL. This produces a large difference in the magnitudes of the driving currents between the pixel PX in the mth row and the pixel PX in the (m+1)th row.

According to the investigation by the present inventor, this variation in threshold voltage is caused by ion doping for the channel region CH of the polycrystalline semiconductor layer SC, i.e., channel doping. That is, the variation in threshold value is caused by the variation in impurity concentration in the channel region CH of the polycrystalline semiconductor layer SC.

It is extremely difficult to eliminate the variation in impurity concentration in the channel region CH throughout the whole display area. However, in a very narrow area, e.g., in an area occupied by one pixel PX, the impurity concentration in the region CH is substantially uniform. This embodiment prevents display unevenness by using this phenomenon as will be explained below.

Letting W1, L1, μ1, C_{OX}1, V_{gs}1, and Vₜₕ1 be the channel width, channel length, carrier mobility, gate oxide film capacitance, gate-to-source voltage, and threshold voltage, respectively, of the first drive control element DR1. Also, letting W2, L2, μ2, C_{OX}2, V_{gs}2, and Vₜₕ2 be the channel width, channel length, carrier mobility, gate oxide film capacitance, gate-to-source voltage, and threshold voltage, respectively, of the second drive control element DR2.

In this case, a drain current I_{d}1 of the first drive control element DR1 in a saturation region and a drain current I_{d}2 of the second drive control element DR2 in a saturation region can be represented by the following equations (1) and (2), respectively.

$$\begin{matrix}{I}_{d} 1 = \frac{1}{2} ⨯ \frac{W1}{L1} ⨯ μ 1 ⨯ {C}_{ox} ⨯ {( {V}_{gs} 1 - {V}_{th} 1 )}^{2} = K1 ⨯ {( {V}_{gs} 1 - {V}_{th} 1 )}^{2} & ( 1 ) \\ {I}_{d} 2 = \frac{1}{2} ⨯ \frac{W2}{L2} ⨯ μ 2 ⨯ {C}_{ox} ⨯ {( {V}_{gs} 2 - {V}_{th} 2 )}^{2} = K2 ⨯ {( {V}_{gs} 2 - {V}_{th} 2 )}^{2} & ( 2 )\end{matrix}$$

The drain currents I_{d}1 and I_{d}2 are equal to each other, and equal to the electric current I_{sig} during writing. Also, during writing, the gate-to-source voltage V_{gs}1 is equal to the difference between the gate potential V_{g}1 of the first drive control element DR1 and an electric potential PV_{dd} of the first power supply terminal ND1, and the gate-to-source voltage V_{gs}2 is equal to the difference between the gate potential V_{g}2 of the second drive control element DR2 and the electric potential V_{sig} of the node ND3. Furthermore, the gate potentials V_{g}1 and V_{g}2 are equal to each other. Accordingly, the following equations (3) and (4) are derived from the equations (1) and (2), respectively.
I_{sig}=K1×(V_{g}−PV_{dd}−Vₜₕ1)² (3)
I_{sig}=K2×(V_{g}−V_{sig}−Vₜₕ2)² (4)

In addition, equations (5) and (6) below are obtained by rewriting the equations (3) and (4), respectively.

$$\begin{matrix}\sqrt{\frac{{I}_{sig}}{K1} =} - ( {V}_{g} - {PV}_{dd} - {V}_{th} 1 ) & ( 5 ) \\ \sqrt{\frac{{I}_{sig}}{K2} =} {V}_{g} - {V}_{sig} - {V}_{th} 2 & ( 6 )\end{matrix}$$

Equation (7) below is obtained by adding the left and right sides of the equation (5) to the left and right sides, respectively, of the equation (6), and rewriting the obtained equation.

$${V}_{sig} = {PV}_{dd} - ( \frac{1}{\sqrt{K1}} + \frac{1}{\sqrt{K2}} ) \times \sqrt{{I}_{sig}} + ( {V}_{th} 1 - {V}_{th} 2 ) \qquad ( 7 )$$

As indicated by the equation (7), during a write period, the threshold voltages Vₜₕ1 and Vₜₕ2 of the first and second drive control elements DR1 and DR2 can influence the electric potential V_{sig} of the video signal line DL, which makes the electric current I_{sig} corresponding to a certain gray scale flow.

As described above, however, in a very narrow area such as an area occupied by one pixel PX, the impurity concentration in the channel region CH is substantially uniform. Also, the change in threshold voltage caused by channel doping described previously remains the same regardless of the conduction type. Therefore, even if the threshold voltages Vₜₕ1 and Vₜₕ2 vary between the pixels PX, the difference (Vₜₕ1−Vₜₕ2) between the threshold voltages Vₜₕ1 and Vₜₕ2 hardly varies between the pixels PX. That is, the difference (Vₜₕ1−Vₜₕ2) in the equation (7) can be regarded as a constant.

As described above, this embodiment can eliminate the influence of the threshold voltages Vₜₕ1 and Vₜₕ2 on the electric potential V_{sig}. Accordingly, this embodiment can prevent display unevenness caused by the variations in threshold voltages of the drive control elements.

A case in which the configuration shown in FIG. 1 is employed in a pixel circuit is explained above. However, the above effects can also be obtained when another configuration is employed in a pixel circuit.

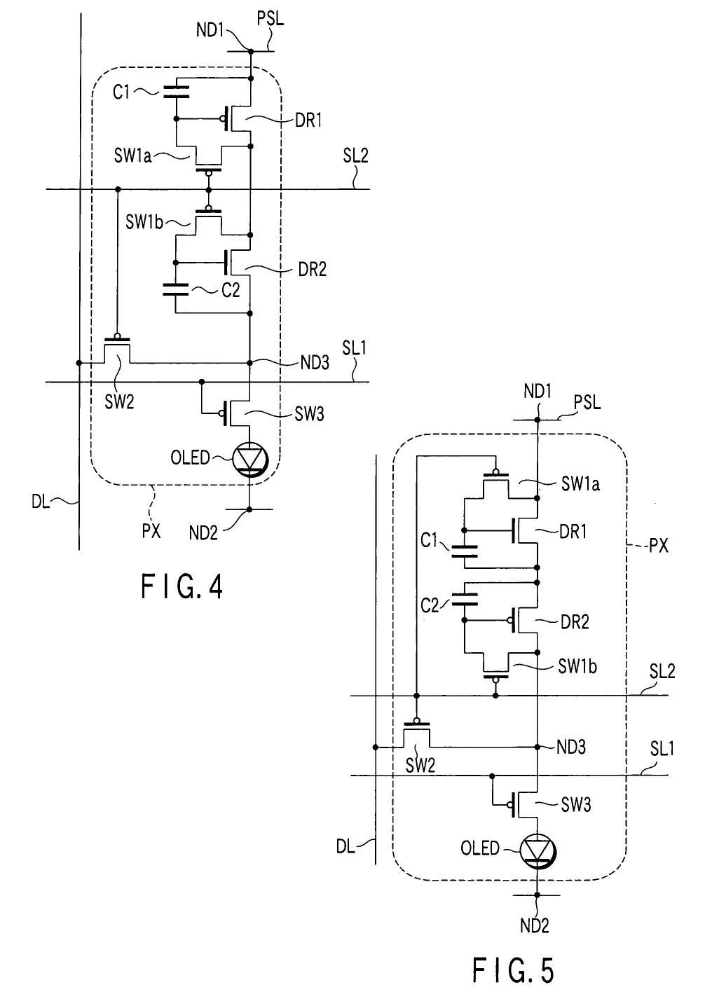

FIG. 4 is an equivalent circuit diagram showing a modification of the pixel of FIG. 1. A display employing the arrangement of FIG. 4 in the pixel PX can be driven by the same method as described above with reference to FIG. 3. Also, when the arrangement shown in FIG. 4 is employed in the pixel PX, the same effects as when the arrangement shown in FIG. 1 is employed in the pixel PX can be obtained.

The pixel PX shown in FIG. 4 has substantially the same configuration as the pixel PX shown in FIG. 1. In the pixel PX shown in FIG. 4, however, the first capacitor C1 is connected between the first power supply terminal ND1 and the gate of the first drive control element DR1.

The first capacitor C1 need not be connected between the constant-potential terminal ND4 and the gate of the first drive control element DR1 as shown in FIG. 1, and may, in stead, be connected between the gate and source of the first drive control element DR1 as shown in FIG. 4.

The second embodiment of the present invention will be described below.

FIG. 5 is an equivalent circuit diagram of a pixel included in a display according to the second embodiment of the present invention.

The display is an active matrix display, e.g., an active matrix organic EL display. The display has the same structure as the display shown in FIG. 1 except that the following configuration is employed in each pixel PX.

That is, in this display, a first drive control element DR1 is an n-channel TFT, and a second drive control element DR2 is a p-channel TFT. The drain of the first drive control element DR1 is connected to a node ND1. The second drive control element DR2 has a source connected to the source of the first drive control element DR1, and a drain connected to a node ND3. A diode-connecting switch SW1a is connected between the gate and drain of the first drive control element DR1, and a capacitor C1 is connected between the gate and source of the first drive control element DR1. A diode-connecting switch SW1b is connected between the gate and drain of the second drive control element DR2, and a capacitor C2 is connected between the gate and source of the second drive control element DR2. The capacitors C1 and C2 hold the gate-to-source voltages of the first and second drive control elements DR1 and DR2, respectively.

The display can be driven by the same method as described above with reference to FIG. 3. Also, when the arrangement shown in FIG. 5 is employed in the pixel PX, the same effects as when the arrangement shown in FIG. 1 is employed in the pixel PX can be obtained as will be explained below.

As explained in the first embodiment, a drain current I_{d}1 of the first drive control element DR1 in a saturation region and a drain current I_{d}2 of the second drive control element DR2 in a saturation region can be represented by the equations (1) and (2), respectively.

The drain currents I_{d}1 and I_{d}2 are equal to each other, and equal to an electric current I_{sig} during writing. Also, during writing, a gate-to-source voltage V_{gs}1 of the first drive control element DR1 is equal to the difference between an electric potential PV_{dd} of the node ND1 and a source potential Vₛ1 of the first drive control element DR1, and a gate-to-source voltage V_{gs}2 of the second drive control element DR2 is equal to the difference between an electric potential V_{sig} of the node ND3 and a source potential Vₛ2 of the second drive control element. Furthermore, the source potentials Vₛ1 and Vₛ2 are equal to each other. Accordingly, letting Vₛ be this source potential, equations (8) and (9) below are obtained from equations (1) and (2), respectively.
I_{sig}=K1×(PV_{dd}−Vₛ−Vₜₕ1)² (8)
I_{sig}=K2×(V_{sig}−Vₛ−Vₜₕ2² (9)

In addition, equations (10) and (11) below are obtained by changing equations (8) and (9), respectively.

$$\begin{matrix}\sqrt{\frac{{I}_{sig}}{K1}} = ( {PV}_{dd} - {V}_{s} - {V}_{th} 1 ) & ( 10 ) \\ \sqrt{\frac{{I}_{sig}}{K2}} = - ( {V}_{sig} - {V}_{s} - {V}_{th} 2 ) & ( 11 )\end{matrix}$$

Equation (12) below is obtained by adding the left and right sides of equation (10) to the left and right sides, respectively, of equation (11).

$${V}_{sig} = {PV}_{dd} - ( \frac{1}{\sqrt{K1}} + \frac{1}{\sqrt{K2}} ) \times \sqrt{{I}_{sig}} - ( {V}_{th} 1 - {V}_{th} 2 ) \qquad ( 12 )$$

As in the first embodiment, therefore, this embodiment can prevent display unevenness caused by the variations in threshold voltages of the drive control elements.

A case in which the configuration shown in FIG. 5 is employed in a pixel circuit is explained above. However, the above effects can also be obtained when another configuration is employed in a pixel circuit.

Note that if the threshold voltage of the first drive control element DR1 periodically varies along, e.g., the video signal line DL in a display from which the second drive control element DR2 and the like are omitted, display unevenness may be caused by this variation. To make this display unevenness difficult to perceive, it is necessary to set the threshold voltage variation described above to, e.g., 10 mV or less, and typically, 5 mV or less. In the first and second embodiments, the difference Vₜₕ1−Vₜₕ2 between the threshold voltages of the n- and p-channel TFTs is substantially constant, so this display unevenness can also be suppressed.

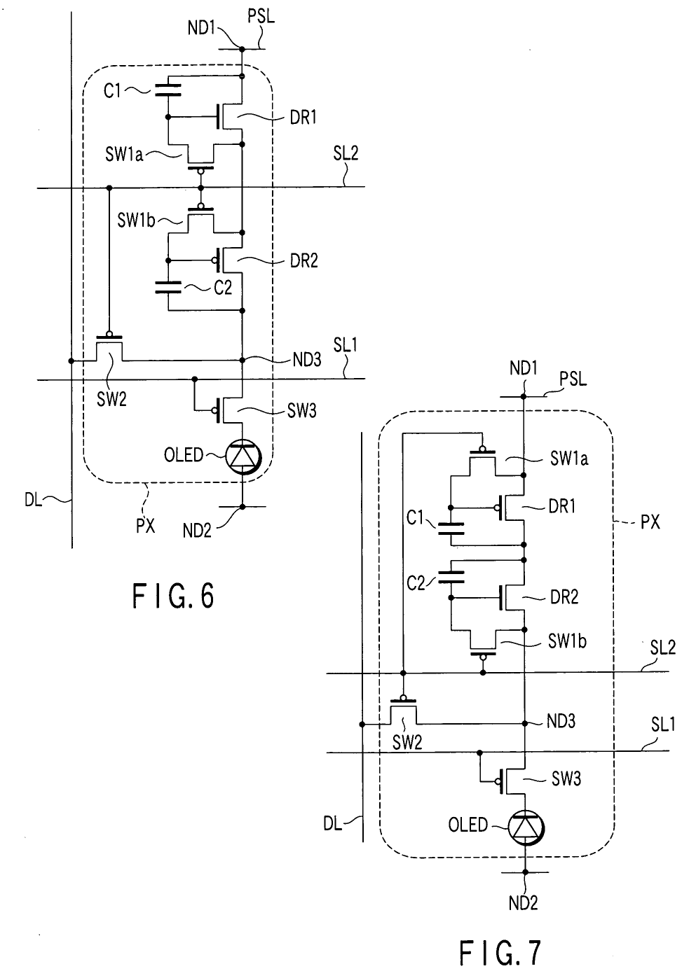

In the first and second embodiments, the electric potential of the first power supply terminal ND1 is set higher than that of the second power supply terminal ND2. However, the electric potential of the second power supply terminal ND2 may also be set higher than that of the first power supply terminal ND1. In this case, as shown in FIGS. 6 and 7, the conduction types of the first and second drive control elements DR1 and DR2 are made opposite to those in the pixel circuits shown in FIGS. 4 and 5.

Also, in the first and second embodiments, the scan signal line SL2 is shared by the diode-connecting switches SW1a and SW1b and video signal supply control switch SW2. However, it is also possible to separately form a scan signal line for controlling the switching operations of the diode-connecting switches SW1a and SW1b, and a scan signal line for controlling the switching operation of the video signal supply control switch SW2.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A display comprising an insulating substrate, pixels arrayed in a matrix form on the insulating substrate, and video signal lines arranged correspondently with columns which the pixels form, wherein each of the pixels comprises:
a first thin film transistor;
a second thin film transistor different in conduction type from the first thin film transistor, the first and second thin film transistors being connected in series between a first power supply terminal and an input/output terminal in this order;
a first capacitor connected between a gate of the first thin film transistor and a constant potential terminal;
a first diode-connecting switch connected between the gate and drain of the first thin film transistor;
a second capacitor connected between gate and source of the second thin film transistor;
a second diode-connecting switch connected between the gate and drain of the second thin film transistor;
a display element;
an output control switch, the output control switch and the display element being connected in series between the input/output terminal and a second power supply terminal in this order; and
a video signal supply control switch connected between the input/output terminal and the video signal line.

2. The display according to claim 1, wherein the first thin film transistor is a p-channel thin film transistor, and the second thin film transistor is an n-channel thin film transistor.

3. The display according to claim 1, wherein the first thin film transistor is an n-channel thin film transistor, and the second thin film transistor is a p-channel thin film transistor.

4. The display according to claim 1, wherein a source of the first thin film transistor is connected to the first power supply terminal, the source of the second thin film transistor is connected to the input/output terminal, and the drain of the first thin film transistor is connected to the drain of the second thin film transistor.

5. The display according to claim 1, wherein the drain of the first thin film transistor is connected to the first power supply terminal, the drain of the second thin film transistor is connected to the input/output terminal, and a source of the first thin film transistor is connected to the source of the second thin film transistor.

6. The display according to claim 1, further comprising first and second scan signal lines arranged correspondently with rows which the pixels form, wherein a control terminal of the output control switch is connected to the first scan signal line, and control terminals of the first and second diode-connecting switches are connected to the second scan signal line.

7. The display according to claim 6, wherein the first diode-connecting switch is a thin film transistor, and the second diode-connecting switch is a thin film transistor whose conduction type is the same as that of the first diode-connecting switch.

8. The display according to claim 1, wherein the sources and drains of the first and second thin film transistors are formed in polycrystalline semiconductor layers.

9. The display according to claim 8, wherein the polycrystalline semiconductor layers are polycrystalline silicon layers.

10. The display according to claim 1, wherein the display element is an organic EL element.

11. An array substrate comprising an insulating substrate, pixel circuits arrayed in a matrix form on the insulating substrate, and video signal lines arranged correspondently with columns which the pixel circuits form, wherein each of the pixel circuits comprises:
a first thin film transistor;
a second thin film transistor different in conduction type from the first thin film transistor, the first and second thin film transistors being connected in series between a power supply terminal and an input/output terminal in this order;
a first capacitor connected between a gate of the first thin film transistor and a constant potential terminal;
a first diode-connecting switch connected between the gate and drain of the first thin film transistor;
a second capacitor connected between gate and source of the second thin film transistor;
a second diode-connecting switch connected between the gate and drain of the second thin film transistor;
a pixel electrode;
an output control switch connected between the input/output terminal and the pixel electrode; and
a video signal supply control switch connected between the input/output terminal and the video signal line.

12. The array substrate according to claim 11, wherein the first thin film transistor is a p-channel thin film transistor, and the second thin film transistor is an n-channel thin film transistor.

13. The array substrate according to claim 11, wherein the first thin film transistor is an n-channel thin film transistor, and the second thin film transistor is a p-channel thin film transistor.

14. The array substrate according to claim 11, further comprising first and second scan signal lines arranged correspondently with rows which the pixel circuits form, wherein a control terminal of the output control switch is connected to the first scan signal line, and control terminals of the first and second diode-connecting switches are connected to the second scan signal line.

15. The array substrate according to claim 14, wherein the first diode-connecting switch is a thin film transistor, and the second diode-connecting switch is a thin film transistor whose conduction type is the same as that of the first diode-connecting switch.

16. The array substrate according to claim 11, wherein the sources and drains of the first and second thin film transistors are formed in polycrystalline semiconductor layers.

17. The array substrate according to claim 16, wherein the polycrystalline semiconductor layers are polycrystalline silicon layers.

18. A method of manufacturing the display according to claim 1, comprising:
forming first and second semiconductor layers in which the sources and drains of the first and second thin film transistors are to be formed, respectively, at positions on the insulating substrate corresponding to the pixels; and
simultaneously executing channel doping for the first semiconductor layer and channel doping for the second semiconductor layer at each of the positions corresponding to the pixels.

19. The method according to claim 18, wherein the channel doping for the first and second semiconductor layers includes irradiating the first and second semiconductor layers with ion beam as line beam, and shifting a position of an irradiated area on the insulating substrate which is irradiated with the ion beam in a direction crossing a longitudinal direction of the irradiated area.

20. The method according to claim 18, wherein the first and second semiconductor layers are polycrystalline silicon layers.

21. The method according to claim 18, wherein the display element is an organic EL element.
